(19) United States
(12) Patent Application Publication
(10) Pub. No.: US 2014/0178681 A1
(43) Pub. Date: Jun. 26, 2014

(54) METHODS OF MODULATING TACKINESS

(71) Applicants: Robin E. Wright, Inver Grove Heights, MN (US); Nedlin B. Johnson, Minneapolis, MN (US); Hal A. LaFleur, III, Woodbury, MN (US)

(72) Inventors: Robin E. Wright, Inver Grove Heights, MN (US); Nedlin B. Johnson, Minneapolis, MN (US); Hal A. LaFleur, III, Woodbury, MN (US)

(73) Assignee: 3M INNOVATIVE PROPERTIES COMPANY, St. Paul, MN (US)

(21) Appl. No.: 14/236,358

(22) PCT Filed: Sep. 12, 2012
(86) PCT No.: PCT/US2012/054824

§ 371 Date: Jan. 31, 2014

Related U.S. Application Data
(60) Provisional application No. 61/534,508, filed on Sep. 14, 2011.
(60) Provisional application No. 61/617,730, filed on Mar. 30, 2012.

(51) Int. Cl. H01J 37/32; G21K 5/00

(52) U.S. Cl. CPC H01J 37/32; G21K 5/00; H01J 37/32018
USPC 428/345; 250/492.1

(57) ABSTRACT

Methods of modulating tackiness of a substrate bearing an adhesive. The method includes modulating the tackiness of a layer of adhesive by subjecting the layer of the adhesive to radiant output from a radiation source. At least a portion of the radiant output has a wavelength of less than 200 nanometers.

### TECHNICAL FIELD

The present disclosure relates to tackiness modulation of substrates bearing an adhesive and, particularly, to the use of radiation to modulate tackiness of adhesive-coated substrates.

### SUMMARY

In some aspects, a method of modulating tackiness of a substrate bearing an adhesive is provided. The method includes providing a substrate that includes a first major surface and a second major surface. One or more layers of an adhesive composition are disposed on at least a portion of either or both of the first major surface and the second major surface. The method further includes modulating the tackiness of the layer of adhesive by subjecting the layer of the adhesive to radiant output from a radiation source. At least a portion of the radiant output has a wavelength of less than 200 nanometers.

The tackiness modulation methods disclosed herein have numerous advantages over known tackiness modulation methods. For example, the tackiness modulation methods of the present disclosure allow one to obtain adhesive coated substrates with a variety of adhesive properties (e.g., tackiness level) using one coating fluid composition and, optionally, during the same coating operation using the same coating equipment. This can be accomplished by varying, for example, the level of radiation and/or the time of the radiation exposure. Additionally, the present methods allow for tackiness modulation without the need to apply additional coatings (e.g., application of powders, particulates, solutions, gels, pastes or any other contact/chemical coating treatment), which can adversely affect manufacturing efficiency and cost. Still further, the present tackiness modulation methods can be used to modulate the tackiness of only a superficial segment of the one or more adhesive layers. Consequently, the methods allow for tackiness modulation without affecting the bulk adhesive properties of the one or more adhesive layers.

The above summary of the present disclosure is not intended to describe each embodiment of the present invention. The details of one or more embodiments of the disclosure are also set forth in the description below. Other features, objects, and advantages of the invention will be apparent from the description and from the claims.

### DETAILED DESCRIPTION

The present disclosure relates to tackiness modulation of substrates bearing an adhesive and, particularly, to the use of radiation to modulate tackiness of adhesive-coated substrates.

Often times, adhesive coated substrates are produced via a coating process in which a web of a substrate is conveyed past a coating applicator that deposits one or more layers of an adhesive composition onto a major surface of the web.

Today, there is a need for adhesive coated substrates of varying degrees of adhesion, or tackiness. While this may be accomplished by, for example, reformulating the adhesive composition deposited by the coating applicator and/or the addition of superficial coatings (e.g., powders, particulates, gels, pastes) to the adhesive, it would be advantageous, in terms of both cost and efficiency, if such modulation in tackiness could be produced utilizing a process that does not require variation in coating applicators, variation in adhesive composition deposited by the applicator (i.e., reformulation of the adhesive composition), and/or the introduction of additional coatings onto the adhesive.

As used herein, including the claims, the term “penetration depth” refers to the distance into a coating at which the Beer-Lambert absorption of incident radiation at the principle wavelength responsible for tackiness modulation exceeds about 95%.

As used herein, including the claims, the term “(co)polymer” means a homopolymer or a copolymer.

As used herein, including the claims, the term “(meth)acrylic” with respect to a monomer means a vinyl-functional alkyl ester formed as the reaction product of an alcohol with an acrylic or a methacrylic acid, for example, acrylic acid or methacrylic acid. With respect to a (co)polymer, the term means a (co)polymer formed by polymerizing one or more (meth)acrylic monomers.

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the content clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

In accordance with exemplary embodiments of the present disclosure, one or more major surfaces of a substrate bear one or more layers of adhesive thereon, and the one or more layers of adhesive are subjected to selected irradiation to modulate the tackiness of the adhesive. For example, a lowering of the tackiness level of the one or more adhesive layers may occur by exposure to the selected radiation. Prior to radiation exposure, the one or more adhesive layers, for example, the exposed surface of the one or more adhesive layers, need not be subjected to a pre-treatment that achieves and/or facilitates modulation of the tackiness of the adhesive (e.g., application of powders, particulates, solutions, gels, pastes or any other contact/chemical coating treatment). The tack modulation methods of the present disclosure may allow for precise control of the tackiness of adhesive coated substrates without the need for multiple adhesive coating formulations. Furthermore, the tack modulation methods of the present disclosure may affect only a superficial segment of the one or more adhesive layers. In this manner, while adequately modulating the tackiness of the adhesive layers, the present methods do not adversely affect the bulk adhesive properties of the adhesive layers.

A process in accordance with some embodiments of the present disclosure may include subjecting one or more layers of an adhesive disposed on a substrate to irradiation. The substrate may be formed as a continuous web of material. Alternatively, the substrate may be formed as two or more web segments separated by, for example, cuts, score lines, perforations, or the like. The substrate may have any shape and thickness. The substrate may include a first, or upper major surface and a second, or lower major surface opposite the upper major surface. Either or both of the upper major surface and the lower major surface may have one or more layers of an adhesive composition disposed thereon. The one or more layers of the adhesive composition may be disposed on the surface as a continuous coating (i.e., disposed on all or nearly all of the surface area of the major surface) or as a discontinuous coating (e.g., stripes, lines, pads, grids, or any desired pattern).

In various embodiments, the substrate may include, without limitation, cellophane, acetate, fiber, polyester, vinyl, polyethylene, polypropylene including, e.g., monoaxially oriented polypropylene and biaxially oriented polypropylene, polytetrafluoroethylene, polyvinylfluoroethylene, polyurethane, polyimide, paper (e.g., polycoated Kraft paper, and supercalendered or glassine Kraft paper), woven webs (e.g., cotton, polyester, nylon and glass), nonwoven webs, foil (e.g., aluminum, lead, copper, stainless steel and brass foil tapes) and combinations thereof.

In illustrative embodiments, the adhesive layers (or a precursor to the adhesive layer) can be solvent borne, waterborne, or solvent-free and may be applied to a major surface of the substrate via any coating method including, without limitation, roll coating, knife coating, hot melt coating, spray coating, vapor coating, or curtain coating. If an adhesive precursor composition is employed, such composition can be converted to an adhesive composition on the substrate using methods known to those skilled in the art.

In various embodiments, the one or more layers of the adhesive composition can be disposed on the substrate at a thickness of less than 1000 micrometers, less than 100 micrometers, less than 10 micrometers, or even less than 1 micrometer. The one or more layers of the adhesive composition can be disposed on the substrate within a thickness range of 0.1 micrometers-1000 micrometers, 1.0 micrometers-750 micrometers, 10 micrometers-500 micrometers, or 15 micrometers-250 micrometers. It is to be appreciated that the foregoing thickness values may refer to the thickness of the one or more adhesive layers after a solvent removal step, if necessary, is performed.

In some embodiments, the adhesive composition may include a pressure sensitive adhesive. Pressure sensitive adhesives useful in the methods of the present disclosure may include, without limitation, natural rubber, styrene butadiene rubber, styrene-isoprene-styrene (co)polymers, styrene-butadiene-styrene (co)polymers, polyacrylates including (meth)acrylic (co)polymers, polyolefins such as polyisobutylene and polyisoprene, polyurethane, polyvinyl ethyl ether, polysiloxanes, silicones, polyurethanes, polyureas, and blends thereof.

In various embodiments, the pressure sensitive adhesives useful in the methods of the present disclosure may be UV-polymerized pressure sensitive adhesives. For purposes of the present disclosure, including the claims, the term “UV-polymerized pressure sensitive adhesives” may refer to pressure sensitive adhesives formed by polymerization of a pressure sensitive adhesive precursor composition (e.g., one or more mono-, di-, or polyfunctional monomers and/or oligomers) that may or may not include a photoinitiator, by exposure of the precursor composition to UV radiation. Examples of photoinitiators that may be utilized include free radical photoinitiators such as benzoin and its derivatives, benzil ketals, acetophenone and its derivatives, benzophenone and its derivatives, and phosphine oxides, as well as cationic photoinitiators such as onium salts including diaryl iodonium and triarylsulfonium salts.

In other embodiments, the pressure sensitive adhesives useful in the methods of the present disclosure may be non-UV-polymerized pressure sensitive adhesives. Polymerization methods for such non-UV-polymerized pressure sensitive adhesives include, without limitation, thermal, e-beam, and gamma-ray treatment. It is to be appreciated that non-UV polymerization methods do not require the use of a photoinitiator. Therefore, non-UV-polymerized pressure sensitive adhesives (as well as their pressure sensitive adhesive precursor compositions) useful in the methods of the present disclosure may not include any amount of a photoinitiator.

In illustrative embodiments, the adhesive compositions useful in the methods of the present disclosure may include one or more additives. Additives may include, without limitation, tackifiers, plasticizers, pigments, dyes, and/or fillers.

Methods of modulating tack in accordance with embodiments of the present disclosure may include subjecting one or more layers of an adhesive disposed on a substrate, for example, one or more major surfaces of a substrate, to irradiation. During the exposure, the substrate may be stationary, or alternatively, may be under transport via a suitable conveying apparatus.

In some embodiments, the radiation source is non-ionizing. In further embodiments, the non-ionizing radiation source is an ultraviolet light source. Ultraviolet light sources useful in the methods of the present disclosure may include those having at least a portion (e.g., at least 5%, at least 10%, at least 25%, or at least 50%) of their radiant output at wavelengths of less than 240 nm, less than 200 nm, less than 180 nm, less than 170 nm, less than 150 nm, or even as low as 120 nm. The ultraviolet light sources may include those having at least a portion (e.g., at least 5%, at least 10%, at least 25%, or at least 50%) of their radiant output at wavelengths ranging between about 160 nm and about 240 nm, or between about 170 nm and about 200 nm. The ultraviolet light sources may include, but are not limited to, deuterium lamps, low-pressure mercury lamps, low-pressure mercury amalgam lamps, pulsed xenon sources, excimer lasers, and excimer lamps. Examples of excimer ultraviolet light sources include lamps such as those commercially available from Osram (Massachusetts, United States), Heraeus-Noblelight (Hanau, Germany), Ushio (Tokyo, Japan), and those described in Kogelschatz, Applied Surface Science, 54 (1992), 410-423, glow discharge lamps such as those described in EP Patent Appl. 521,553 (assigned to N. V. Philips), microwave driven lamps such as those described in Kitamura et al., Applied Surface Science, 79/80 (1994), 507-513 and DE 4302555 A1 (assigned to Fusion Systems), and excimer lamps pumped by a volume discharge with ultraviolet preionization as described in Tech. Phys, 39(10), 1054 (1994).

In still further embodiments, the radiation source may be a glow discharge from a plasma source. Such sources may involve excitation of a carrier gas (e.g. nitrogen) to generate electrons, ions, radicals, and photons. As reported in, for example, Elsner, et. al. [Macromol. Mater. Eng. 2009, 294, 422-31], a variety of acrylate monomers can be cured in the absence of photoinitiators using a nitrogen plasma polymerization process in which UV spectral lines, including bands near 150 nm, 175 nm, and 220 nm were observed.

In some embodiments, exposure to the radiation source may be carried out in a controlled environment (e.g., chamber) that is substantially free of oxygen. Substantially oxygen free environments may be particularly useful in embodiments in which the radiation source has radiant output at wavelengths of less than about 200 nm. In such embodiments, oxygen gas present in the environment may absorb the UV radiation, thereby substantially preventing the radiation from reaching the target surface. In one embodiment, the methods of the present disclosure may be carried out in an inert environment including an inert gas such as nitrogen. In embodiments in which an inert gas is used, oxygen levels in the environment may be as low as 50 ppm, 25 ppm, or even as low as 10 ppm, and as high as 100 ppm, 500 ppm, or even as high as 1000 ppm. In further embodiments, the controlled environment may be operated at a vacuum pressure. In embodiments in which vacuum pressures are employed, the pressures may as low as 10⁻⁴ torr, 10⁻⁵ torr, or even as low as 10⁻⁶ torr, and be as high as 10⁻³ torr, as high as 10⁻² torr, as high as 10⁻¹ torr, as high as 1 torr, as high as 10 torr, or even as high as 100 torr.

The irradiance or incident radiation levels useful in the methods of the present disclosure can be as low as 10 mW/cm², 1 mW/cm², 0.1 mW/cm², or even as low as 0.010 mW/cm² , and as high as 1 W/cm², 2 W/cm², 5 W/cm², or even as high as 10.0 W/cm². In some embodiments, incident radiation levels useful in the methods of the present disclosure can range from about 0.010 mW/cm² to about 2.0 W/cm², about 0.1 mW/cm² to about 1.0 W/cm², or about 1.0 mW/cm² to about 100 mW/cm².

In some embodiments, the tack modulation methods of the present disclosure may allow for precise control of the tackiness level of the one or more adhesive layers disposed on the substrate. For example, by controlling any or all of: (i) the gap between the radiation source and the major surface bearing the adhesive layer; (ii) the radiation level/intensity; and (iii) the exposure time of the adhesive layer to incident radiation, a desired degree of tackiness modulation of a particular adhesive composition may be achieved. By controlling the radiation exposure variables in this manner, adhesive coated substrates with any desired level of tackiness (less than the tackiness of the adhesive layer as coated) may be obtained. Moreover, by allowing for such precise control through adjustment of radiation exposure variables only, the methods may be carried out during a single coating operation, using a single set of coating equipment that deposits a single adhesive coating fluid. Other factors that may be controlled to impact the degree of tack modulation include the area or pattern of the exposure, the level of oxygen present, and/or the gas composition of a plasma discharge.

In various embodiments, the tack modulation methods of the present disclosure may accommodate modulation of only a superficial thickness segment of the adhesive layer disposed on the substrate (i.e., a thickness segment of the adhesive layer furthest from the substrate). For example, in some embodiments, in a similar manner to that described above, the adhesive layers may be exposed to radiation under conditions selected such that the penetration depth of the radiation to which the adhesive layer is exposed may be less than 10 microns, less than 5 microns, less than 1 micron, or even less than 100 nanometers. In this manner, the irradiation treatments of the present disclosure may not affect (i.e., modulate to any extent) the bulk adhesive properties of the adhesive layer. Consequently, the methods of the present disclosure may not have a deleterious or altering effect on the cohesive strength or bulk crosslink density of the adhesive layers, thereby advantageously maintaining, for example, the stiffness properties, creep behavior, and/or high temperature shear performance of the adhesive layers.

In illustrative embodiments, the methods of the present disclosure may accommodate selective modulation of the tackiness of the one or more adhesive layers. For example, the methods of the present disclosure may include placing a masking device proximate the major surface of the substrate during ultraviolet radiation exposure. The masking device may include one or more cut-out portions defining parts of the one or more adhesive layers to be modulated and parts to remain unmodulated. The masking device may be formed of any material sufficient to prevent transmission of the ultraviolet radiation therethrough. The cut-out portions may be arranged in any desired configuration such as stripes, lines, pads, grids, or any other desired pattern. In this manner, the methods of the present disclosure may allow for selectively modulating the tackiness of the one or more adhesive layers.

In various embodiments, the adhesive coated, and tackiness modulated substrates of the present disclosure may, in a subsequent processing step, be rolled to form rolls of adhesive tape. For example, the adhesive coated substrates may be described as backing layers having an adhesive coating disposed on a major surface thereof, which can be rolled to from an adhesive tape roll. Such adhesive tape rolls may further include a release coating, or low adhesion backsize, disposed on a second major surface of the substrate. Alternatively, the adhesive tape rolls may further include a release liner (which may have a release coating disposed on a major surface thereof) in contact with the adhesive coated major surface of the backing layer. As another example, the adhesive coated substrates may be used to form adhesive tape rolls that include a release liner comprising a release coating disposed on at least a portion of each of its major surfaces and an adhesive coating deposited over one of the release coatings. Examples of suitable release coating compositions include, without limitation, silicones, fluorocarbons, and polyolefins including, e.g., polyethylene and polypropylene. The backing layers and, when present, release liners, can also include reinforcing agents including, without limitation, fibers, filaments (e.g., glass fiber filaments), and saturants (e.g., synthetic rubber latex saturated paper backings). Common types of adhesive tapes that can be formed utilizing the adhesive coated substrates of the present disclosure include masking tape, electrical tape, duct tape, filament tape, medical tape, transfer tape, and the like.

### EXAMPLES

The operation of the present disclosure will be further described with regard to the following detailed examples. These examples are offered to further illustrate the various specific and preferred embodiments and techniques. It should be understood, however, that many variations and modifications may be made while remaining within the scope of the present disclosure.

### Materials

TABLE 1
MATERIALS USED IN THE PREPARATION OF THE EXAMPLES

| I.D. | Description | Source |
|---|---|---|
| Adhesive | VHB ™ 4991; double-sided, pressure-sensitive, acrylic foam | 3M Company, |
| Tape 1 | tape with PE film liner, 75 mil thick | St. Paul, MN, |
| | | USA |
| Adhesive | Acrylic Tape (black, single sided adhesive) | 3M Company, |
| Tape 2 | | St. Paul, MN, |
| | | USA |
| Adhesive | Diaper tape, CFT-01424 | 3M Company, |
| Tape 3 | | St. Paul, MN, |
| | | USA |
| Adhesive | Black vinyl electrical tape, Scotch ™ Super 33+ | 3M Company, |
| Tape 4 | | St. Paul, MN, |
| | | USA |
| Adhesive | Silicone adhesive on paper backing | 3M Company, |
| Tape 5 | | St. Paul, MN, |
| | | USA |
| Adhesive | ScotchBlue ™ Painter's Tape Original Multi-Surface 2090 | 3M Company, |
| Tape 6 | | St. Paul, MN, |
| | | USA |

### Test Methods

### Polyken Probe Tack Method:

Adhesion, or tackiness, of adhesive tape specimens was measured using a Polyken Probe Tack Tester, Series 400. The probe dwell time was 1 second and the probe withdrawal speed was 1 cm/sec. A 1 square inch (6.45 square cm) sample of tape was placed adhesive side down onto a 1″ (2.54 cm) diameter metal disc with a hole in the center. A ⅛″ (3.2 mm) diameter metal probe was then directed upward by the Polyken into the hole and stuck to the adhesive side of the tape for 1 second. The peak grams sensed by the probe during downward withdrawal was then recorded. Four replicates were done for each tape specimen.

Adhesion to Glass Method: IMASS Peel Tester SP-102B-3M90 with 4½ lb. (2.0 kg):

Tackiness of tape specimens using an IMASS Peel Tester SP-102B-3M90 was carried out as follows:

The IMASS Peel Tester was set-up and calibrated in accordance with standard procedure. An end of each sample was then held in hand. The left end of the sample was then contacted with the left end of the glass plate such that it was under the roller. The right end of the sample was held so as to be above the plate. The roller was then lowered to the platen. The roller was adjusted so that it rested squarely on the platen and platen drive was started. Tension sufficient to keep the sample from touching the plate until contact with the roller was applied. The roller was then returned to the stored position and the platen to its starting position. The left end of the tape was then attached to the stirrup and nearly all of the slack was removed by adjusting the platen. The platen drive was then started. Check During the time of the averaging (red LED indicator lit), the samples were monitored to ensure that slack tape or the stirrup suspended in space was not included in that period. After the platen stopped, the Meter Select Switch was adjusted to Average and the value displayed was recorded.

### Comparative Examples C1-C5

The tackiness of samples of Adhesive Tapes 1-5 was measured using the

Polyken Probe Tack Method. The test results are shown in Table 2.

TABLE 2

| | | Rep. 1 | Rep. 2 | Rep. 3 | Rep. 4 | Avg. |
|---|---|---|---|---|---|---|
| Comparative | | (peak | (peak | (peak | (peak | (peak |
| Example No. | Tape | grams) | grams) | grams) | grams) | grams) |
| 1 | Adhesive | 1252 | 1124 | 1143 | 1077 | 1149 |
| | Tape 1 | | | | | |
| 2 | Adhesive | 596 | 545 | 671 | 416 | 557 |
| | Tape 2 | | | | | |
| 3 | Adhesive | 319 | 262 | 382 | 367 | 333 |
| | Tape 3 | | | | | |
| 4 | Adhesive | 356 | 496 | 471 | 533 | 464 |
| | Tape4 | | | | | |
| 5 | Adhesive | 207 | 65 | 115 | 213 | 150 |
| | Tape 5 | | | | | |

### Examples 1-10

### Tackiness Modulation Using Vacuum UV (VUV)

Samples of Adhesive Tapes 1-5 were placed adhesive side up onto a PET film carrier liner. The samples were then run under a 620 mm length Osram Xeradex lamp which emits 172 nm VUV (oriented long side along the web machine direction). The first line speed corresponded to 0.7 minutes of VUV exposure (Examples 1-5) and the adhesive surfaces of the samples were 4″ (10 cm) below the bulb window. The lamp was set at 100% power output. This process was then repeated with the same tape specimens, utilizing a slower line speed corresponding to 2.5 minutes of VUV exposure (Examples 6-10). The chamber was purged with nitrogen gas to an oxygen level of less than 50 ppm during VUV exposure. Following exposure to the VUV, tackiness of the samples was measured using the Polyken Probe Tack Method. The samples were observed to exhibit progressively less tackiness as the exposure to VUV increased. The test results are shown in Table 3.

TABLE 3

| | | Rep. 1 | Rep. 2 | Rep. 3 | Rep. 4 | Avg. |
|---|---|---|---|---|---|---|
| Example | | (peak | (peak | (peak | (peak | (peak |
| No. | Tape | grams) | grams) | grams) | grams) | grams) |
| 1 | Adhesive | 206 | 243 | 252 | 230 | 233 |
| | Tape 1 | | | | | |
| 2 | Adhesive | 220 | 145 | 165 | 184 | 179 |
| | Tape 2 | | | | | |
| 3 | Adhesive | 0 | 0 | 0 | 0 | 0 |
| | Tape 3 | | | | | |
| 4 | Adhesive | 433 | 204 | 159 | 183 | 245 |
| | Tape4 | | | | | |
| 5 | Adhesive | 34 | 33 | 41 | 53 | 40 |
| | Tape 5 | | | | | |
| 6 | Adhesive | 0 | 0 | 0 | 0 | 0 |
| | Tape 1 | | | | | |
| 7 | Adhesive | 0 | 0 | 0 | 0 | 0 |
| | Tape 2 | | | | | |
| 8 | Adhesive | 0 | 0 | 0 | 0 | 0 |
| | Tape 3 | | | | | |
| 9 | Adhesive | 0 | 0 | 0 | 0 | 0 |
| | Tape4 | | | | | |
| 10 | Adhesive | 0 | 0 | 0 | 0 | 0 |
| | Tape 5 | | | | | |

### Examples 11-20

### Tackiness Modulation Using Plasma

A capacitively coupled reactor (Plasmatherm Model 3032, St. Petersburg, Fla.) with a 36″ dia. (91 cm) by 12″ (30.5 cm) high cylindrical reactor vessel was used to modulate the tackiness of a sample of each of Adhesive Tapes 1-5. The reactor was configured for reactive ion etching (RIE) with a 26″ (66 cm) lower powered electrode and central gas pumping. The chamber was pumped by a roots blower (Edwards Model EH1200) backed by a dry mechanical pump (Edwards Model iQDP80). RF power was delivered by a 3 kW, 13.56 Mhz solid-state generator (RFPP Model RF30S) through an impedance matching network. The system had a nominal base pressure of 5 mTorr. The flow rates of the gases were controlled by MKS flow controllers.

Samples of Adhesive Tapes 1-5 were laid adhesive side up on the lower powered electrode of the reactor vessel; the top of the vessel was then closed. The upward facing adhesive was exposed to 2000 W of nitrogen plasma for 1 minute (Examples 11-15). After the plasma treatment was completed, the gases were shut off and the chamber was vented to atmosphere and the specimens were taken out of the chamber. Samples of each of Adhesive Tapes 1-5 were then inserted and the above process was repeated in the same manner except the exposure time was extended to 5 minutes (Examples 16-20). Following exposure to the plasma, the tackiness of the samples was measured using the Polyken Probe Tack Method. There was a reduction in the tackiness of the adhesive exposed to the plasma, with a more dramatic reduction exhibited for the samples exposed for 5 minutes. The test results are shown in Table 4.

TABLE 4

| | | Rep. 1 | Rep. 2 | Rep. 3 | Rep. 4 | Avg. |
|---|---|---|---|---|---|---|
| Example | | (peak | (peak | (peak | (peak | (peak |
| No. | Tape | grams) | grams) | grams) | grams) | grams) |
| 11 | Adhesive | 142 | 128 | 121 | 119 | 128 |
| | Tape 1 | | | | | |
| 12 | Adhesive | 48 | 38 | 48 | 48 | 46 |
| | Tape 2 | | | | | |
| 13 | Adhesive | 0 | 0 | 0 | 0 | 0 |
| | Tape 3 | | | | | |
| 14 | Adhesive | 0 | 0 | 0 | 0 | 0 |
| | Tape 4 | | | | | |
| 15 | Adhesive | 55 | 66 | 82 | 78 | 70 |
| | Tape 5 | | | | | |
| 16 | Adhesive | 0 | 0 | 0 | 0 | 0 |
| | Tape 1 | | | | | |
| 17 | Adhesive | 0 | 0 | 0 | 0 | 0 |
| | Tape 2 | | | | | |
| 18 | Adhesive | 0 | 0 | 0 | 0 | 0 |
| | Tape 3 | | | | | |
| 19 | Adhesive | 0 | 0 | 0 | 0 | 0 |
| | Tape4 | | | | | |
| 20 | Adhesive | 0 | 0 | 0 | 0 | 0 |
| | Tape 5 | | | | | |

### Examples 21-23

### Tackiness Modulation Using Vacuum Ultraviolet Radiation From a Low Pressure Mercury Lamp (Ozone Generating).

A sample of Adhesive Tape 6 was placed adhesive side up on a conveying apparatus and run under a low pressure mercury lamp (ozone generating) in a nitrogen inerted atmosphere at an oxygen level of less than 50 ppm. The peak irradiance at 185 nm was approximately 6 mW/cm². The sample was exposed to radiation using a line speed of 2.5 feet (0.76 meters) per minute (Example 21). Samples of Adhesive Tape 6 were also exposed to radiation at line speeds of 5 feet (1.52 meters) per minute (Example 22), and 10 feet (3.05 meters) per minute (Example 23). The adhesive faces were 1″ (2.54 cm) below the bottom of the lamp. Following UV exposure, the tackiness of ten segments of each sample was measured using the Adhesion to Glass Method. The test results are shown in Table 5.

TABLE 5

| | | Line speed | Adhesion to glass |
|---|---|---|---|
| | Test Segment | (meters/minute) | (ounces/inch) |
| Example 21 | 1 | 0.76 | 243.5 |
| | 2 | 0.76 | 213.1 |
| | 3 | 0.76 | 246.3 |
| | 4 | 0.76 | 219.9 |
| | 5 | 0.76 | 216.5 |
| | 6 | 0.76 | 216.2 |
| | 7 | 0.76 | 219.1 |
| | 8 | 0.76 | 201.7 |
| | 9 | 0.76 | 205.7 |
| | 10 | 0.76 | 226.4 |
| Example 22 | 1 | 1.52 | 409.7 |
| | 2 | 1.52 | 409.5 |
| | 3 | 1.52 | 399.2 |
| | 4 | 1.52 | 393.6 |
| | 5 | 1.52 | 393.8 |
| | 6 | 1.52 | 385.9 |
| | 7 | 1.52 | 367.7 |
| | 8 | 1.52 | 370.3 |
| | 9 | 1.52 | 378.0 |
| | 10 | 1.52 | 352.1 |
| Example 23 | 1 | 3.05 | 524.9 |
| | 2 | 3.05 | 500.5 |
| | 3 | 3.05 | 498.5 |
| | 4 | 3.05 | 500.0 |
| | 5 | 3.05 | 434.1 |
| | 6 | 3.05 | 431.0 |
| | 7 | 3.05 | 482.9 |
| | 8 | 3.05 | 490.0 |
| | 9 | 3.05 | 452.9 |
| | 10 | 3.05 | 527.8 |

Other embodiments of the invention are within the scope of the appended claims.

1. A method of modulating tackiness of a substrate bearing an adhesive, said method comprising:
providing a substrate comprising a first major surface and a second major surface, wherein a layer of an adhesive is disposed on at least a portion of either or both of the first major surface and the second major surface; and
modulating the tackiness of the layer of adhesive without affecting the bulk adhesive properties of the layer of adhesive by subjecting the layer of the adhesive to radiant output from a radiation source, wherein at least a portion of the radiant output has a wavelength of less than 200 nanometers.

2. The method according to claim 1, wherein the radiation source comprises an ultraviolet light source.

3. The method according to claim 2, wherein the ultraviolet light source comprises an excimer lamp, excimer laser, low-pressure mercury lamp, low-pressure mercury amalgam lamp, pulsed xenon lamp, or combinations thereof.

4. The method according to claim 3, wherein the ultraviolet light source comprises a dixenon excimer lamp.

5. The method according to claim 3, wherein the ultraviolet light source comprises a low-pressure mercury lamp.

6. The method according to claim 1, wherein the radiation source comprises a glow discharge from a plasma.

7. The method according to claim 1, wherein the tackiness of the layer of adhesive is modulated to a depth of about 1 micron or less.

8. The method according to claim 1, wherein the tackiness of the layer of adhesive is modulated to a depth of about 100 nanometers or less.

9. The method according to claim 1, wherein the layer of adhesive comprises a pressure sensitive adhesive.

10. The method according to claim 9, wherein the pressure sensitive adhesive comprises a silicone polymer.

11. The method according to claim 9, wherein the pressure sensitive adhesive comprises a (meth)acrylic (co)polymer.

12. The method according to claim 1, wherein the layer of adhesive does not comprise a photoinitiator.

13. The method according to claim 1, wherein the step of subjecting the layer of the adhesive to radiant output from a radiation source is carried out in an environment comprising an oxygen concentration of less than 50 ppm.

14. The method according to claim 1, wherein the subjected layer of the adhesive is substantially free of coatings during the radiation exposure.

15. The method according to claim 1, further comprising positioning a masking device proximate either or both of the first and second major surfaces during the radiation exposure.

16. An article comprising a substrate and a layer of adhesive disposed thereon, wherein the article is produced according to the method of claim 1.
